(19) United States
(12) Patent Application Publication
(10) Pub. No.: US 2026/0106066 A1
(43) Pub. Date: Apr. 16, 2026

(54) COMMON MODE CHOKE COIL DEVICE

(71) Applicant: TOYOTA JIDOSHA KABUSHIKI KAISHA, Toyota-shi (JP)

(72) Inventor: Hiroto MIZUTANI, Takarazuka-shi (JP)

(73) Assignee: TOYOTA JIDOSHA KABUSHIKI KAISHA, Toyota-shi (JP)

(21) Appl. No.: 19/227,726

(22) Filed: Jun. 4, 2025

(30) Foreign Application Priority Data
Oct. 15, 2024 (JP) 2024-180326

(51) Int. Cl. H01F 27/28

(52) U.S. Cl. CPC H01F 27/28

(57) ABSTRACT

The first common mode choke coil and the second common mode choke coil are arranged in parallel so that the annular core is coaxial, the first common mode choke coil and the second common mode choke coil is mounted a pair of facing metal rings formed as an annular metal plate on the opposed annular surface, connecting the pair of facing metal rings to the reference potential. The common mode choke coil device functions as a LCL filter because the pair of facing metal rings functions as a capacitance of a parasitic capacitance corresponding to an area of the opposed surface and a distance of the opposed surface.

### CROSS-REFERENCE TO RELATED APPLICATION

This application claims priority to Japanese Patent Application No. 2024-180326 filed on Oct. 15, 2024. The disclosure of the above-identified application, including the specification, drawings, and claims, is incorporated by reference herein in its entirety.

### BACKGROUND

### 1. Technical Field

The present disclosure relates to a common mode choke coil device.

### 2. Description of Related Art

Hitherto, as this type of technology, there has been proposed a technology in which, in a power supply system, a common mode noise, a normal mode noise, and a reflected noise are reduced to reduce an influence of noise on a driven device (see, for example, Japanese Unexamined Patent Application Publication No. 2023-069646 (JP 2023-069646 A)). The noise may generate a magnetic flux in the core of a common mode choke. Then, an induced electromotive force may be generated in a power supply line by the magnetic flux, and a current may flow to become a reflected noise of the power supply line. In this technology, the reflected noise is reduced by a winding in the core of the common mode choke and a resistor connected to the winding. Even when the noise reflected by the driven device passes through the common mode choke, a CR circuit converts the reflected noise into thermal energy by a resistive component of the resistor and consumes the thermal energy.

### SUMMARY

The common mode choke coil is used for measures against noise as an LC filter or an LCL filter by connecting a Y capacitor. In this case, the size of the magnetic core increases or a high-cost magnetic core having high magnetic permeability needs to be applied. Therefore, there is a concern for an increase in size, weight, and cost.

A main object of a common mode choke coil device of the present disclosure is to achieve a reduction in size and weight.

The common mode choke coil device of the present disclosure adopts the following measures to achieve the above main object.

The common mode choke coil device of the present disclosure is a common mode choke coil device including a first common mode choke coil and a second common mode choke coil.

The first common mode choke coil and the second common mode choke coil are disposed in parallel such that annular cores are coaxial.

A pair of facing metal rings provided as annular metal plates is attached to facing annular surfaces of the first common mode choke coil and the second common mode choke coil.

The facing metal rings are connected to a reference potential.

The common mode choke coil device of the present disclosure includes the first common mode choke coil and the second common mode choke coil. The first common mode choke coil and the second common mode choke coil are disposed in parallel such that the annular cores are coaxial. The facing metal rings are attached to the facing annular surfaces of the first common mode choke coil and the second common mode choke coil. The facing metal rings are provided as the annular metal plates. The facing metal rings are connected to the reference potential. Assuming that the area of the facing surfaces of the facing metal rings is S, the distance between the facing surfaces of the facing metal rings is d, and the dielectric constant is ε, the facing metal rings function as capacitances in which a parasitic capacitance C is calculated by C=ε·S/d. Therefore, the first common mode choke coil, the second common mode choke coil, and the facing metal rings can constitute an LCL filter, and the number of components and the cost can be reduced. As a result, it is possible to reduce the size and weight of the common mode choke coil device.

In the common mode choke coil device of the present disclosure, the facing metal rings may be attached to outsides of windings of the first common mode choke coil and the second common mode choke coil. Alternatively, the facing metal rings may be attached to insides of windings of the first common mode choke coil and the second common mode choke coil.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a configuration diagram illustrating an outline of a configuration of a common mode choke coil device 20 according to an embodiment of the present disclosure; and

FIG. 2 is a configuration diagram illustrating an outline of a configuration of a common mode choke coil device 120 of a comparative example.

### DETAILED DESCRIPTION OF EMBODIMENTS

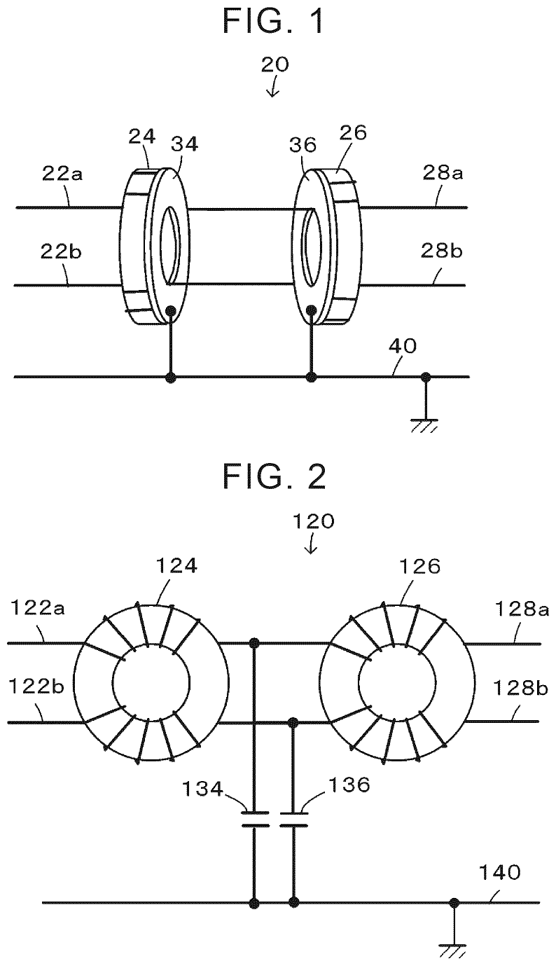

Next, a mode (embodiment) for carrying out the present disclosure will be described. FIG. 1 is a configuration diagram schematically showing a configuration of a common mode choke coil device 20 according to an embodiment of the present disclosure. As illustrated, the common mode choke coil device 20 includes a first common mode choke coil 24, a second common mode choke coil 26, a first facing metal ring 34, and a second facing metal ring 36.

The first common mode choke coil 24 and the second common mode choke coil 26 are configured as well-known common mode choke coils. Specifically, a winding 22a, 28a and a winding 22b, 28b are wound around a core formed in an annular shape by a soft magnetic material such as a nanocrystalline alloy or ferrite. The winding 22a and the winding 22b of the first common mode choke coil 24 are connected to the winding 28a and the winding 28b of the second common mode choke coil 26. The first common mode choke coil 24 and the second common mode choke coil 26 are arranged in parallel so as to be coaxial.

The first facing metal ring 34 and the second facing metal ring 36 are formed in an annular shape of a thin plate, similar to the core of the first common mode choke coil 24, by a chargeable metal plate. The first facing metal ring 34 is attached to a surface of the first common mode choke coil 24 facing the second common mode choke coil 26. The second facing metal ring 36 is attached to a surface of the second common mode choke coil 26 facing the first common mode choke coil 24. That is, the first facing metal ring 34 and the second facing metal ring 36 are attached to opposite surfaces of the first common mode choke coil 24 and the second common mode choke coil 26. The first facing metal ring 34 and the second facing metal ring 36 are connected to the grounded reference potential 40.

Now, consider the common mode choke coil device 120 of the comparative example illustrated in FIG. 2. The comparative common mode choke coil device 120 is a well-known LCL filter. Specifically, the first common mode choke coil 124 and the second common mode choke coil 126 are connected to each other by the winding 122a, 122b and the winding 128a, 128b. The connecting point between the winding 122a, 122b and the winding 128a, 128b is connected to the reference potential 140 via the capacitor 134,136. The reference potential 140 is grounded. In the common mode choke coil device 20 of the embodiment shown in FIG. 1, the first facing metal ring 34 and the second facing metal ring 36 each have an area S, a distance d, and a dielectric constant ε. The common mode choke coil device 20 functions as a capacitance in which the parasitic capacitance C is calculated by C=ε·S/d. Like the common mode choke coil device 120 of the comparative example illustrated in FIG. 2, it functions as a LCL filter. In the common mode choke coil device 20 according to the embodiment, since a capacitor is not required, the number of components and cost can be reduced. As a result, it is possible to reduce the size and weight of the common mode choke coil device.

In the common mode choke coil device 20 of the embodiment described above, the first common mode choke coil 24 and the second common mode choke coil 26 are arranged in parallel so as to be coaxial. Similarly to the core of the first common mode choke coil 24, the first facing metal ring 34 and the second facing metal ring 36, which are formed in an annular shape of a thin plate, are attached to opposite surfaces of the first common mode choke coil 24 and the second common mode choke coil 26. The first facing metal ring 34 and the second facing metal ring 36 are connected to a grounded reference potential 40. Thus, the common mode choke coil device 20 can function as a LCL filter. Since a capacitor is not required, the number of components and cost can be reduced. As a result, it is possible to reduce the size and weight of the common mode choke coil device.

In the common mode choke coil device 20 of the embodiment, the first common mode choke coil 24 wound with the winding 22a, 22b and the second common mode choke coil 26 wound with the winding 28a, 28b are arranged so as to be coaxial with each other. The first facing metal ring 34 and the second facing metal ring 36 are attached to the opposing surface. However, other arrangements may be used. Specifically, a first common mode choke coil configured by winding a winding 22a, 22b in a state where the first facing metal ring 34 is attached to the core, and a second common mode choke coil configured by winding a winding 28a, 28b in a state where the second facing metal ring 36 is attached to the core are prepared. The first common mode choke coil and the second common mode choke coil may be arranged in parallel so as to be coaxial with each other, and the first facing metal ring 34 and the second facing metal ring 36 may be arranged so as to face each other.

The correspondence between the main elements of the embodiments and the main elements of the disclosure described in the column of the means for solving the problem will be described. In the embodiment, the first common mode choke coil 24 corresponds to the “first common mode choke coil”, the second common mode choke coil 26 corresponds to the “second common mode choke coil”, and the first facing metal ring 34 and the second facing metal ring 36 correspond to the “pair of facing metal rings”.

The correspondence between the main elements of the embodiment and the main elements of the disclosure described in the section of the means for solving the problem is an example for specifically explaining the embodiment of the disclosure described in the section of the means for solving the problem. These countermeasures are not intended to limit the elements of the disclosure described in the section for solving the problem. That is, the interpretation of the disclosure described in the section of the means for solving the problem should be performed based on the description in the section, and the embodiments are only specific examples of the disclosure described in the section of the means for solving the problem.

Although the present disclosure has been described above using the embodiment, the present disclosure is not limited to the embodiment in any way, and may be implemented in various modes without departing from the scope of the present disclosure.

The present disclosure is applicable to a manufacturing industry of a common mode choke coil device and the like.

What is claimed is:

1. A common mode choke coil device comprising a first common mode choke coil and a second common mode choke coil, wherein
the first common mode choke coil and the second common mode choke coil are disposed in parallel such that annular cores are coaxial,
a pair of facing metal rings provided as annular metal plates is attached to facing annular surfaces of the first common mode choke coil and the second common mode choke coil, and
the facing metal rings are connected to a reference potential.

2. The common mode choke coil device according to claim 1, wherein the facing metal rings are attached to outsides of windings of the first common mode choke coil and the second common mode choke coil.

3. The common mode choke coil device according to claim 1, wherein the facing metal rings are attached to insides of windings of the first common mode choke coil and the second common mode choke coil.
